(19) United States
(12) Patent Application Publication
(10) Pub. No.: US 2022/0005981 A1
(43) Pub. Date: Jan. 6, 2022

(54) OPTOELECTRONIC DEVICE WITH A MARKER AND METHOD OF MANUFACTURING OPTOELECTRONIC DEVICES

(71) Applicant: OSRAM Opto Semiconductors GmbH, Regensburg (DE)

(72) Inventors: Martin Brandl, Kelheim (DE); Zeljko Pajkic, Regensburg (DE); Dominik Schulten, Regensburg (DE)

(21) Appl. No.: 17/285,724

(22) PCT Filed: Oct. 10, 2019
(86) PCT No.: PCT/EP2019/077475

§ 371 Date: Apr. 15, 2021

(30) Foreign Application Priority Data
Oct. 16, 2018 (DE) 10 2018 125 632.9

(51) Int. Cl. H01L 33/48; H01L 23/544; H01L 23/31; H01L 33/50; H01L 33/10

(52) U.S. Cl. CPC H01L 33/483; H01L 23/544; H01L 2933/0041; H01L 33/502; H01L 33/10; H01L 23/3114

(57) ABSTRACT

A method of manufacturing optoelectronic components includes providing a plurality of optoelectronic semiconductor chips embedded in a carrier layer, wherein a conversion layer is applied to the optoelectronic semiconductor chips and the carrier layer, creating markings in and/or on the conversion layer, and severing the carrier layer to obtain optoelectronic devices, the optoelectronic devices each having at least one of the markings, wherein the at least one marking is at least one recess in the conversion layer.

### TECHNICAL FIELD

This disclosure relates to an optoelectronic device having a marker and to a method of manufacturing optoelectronic devices.

### BACKGROUND

Marking on a surface of optoelectronic components can indicate the polarity or orientation of a semiconductor chip contained in the optoelectronic component, for example, an LED (light emitting diode) semiconductor chip. Such marking is important for process control during assembly of optoelectronic components in end products. In addition, the polarity marking is also beneficial in LED manufacturing and process control during packaging of optoelectronic devices in a packaging belt with a transparent cover tape.

Optoelectronic components often have a conversion layer. Their properties should be affected by the marking only to a small extent, if at all.

There is a need to provide a cost-effective method of manufacturing optoelectronic components, in which markings are to be applied to the optoelectronic components, to apply the markings such that the properties of a conversion layer of the optoelectronic component are not impaired or are impaired only to a small extent, and an optoelectronic component with a marking and a flash light with such an optoelectronic component.

### SUMMARY

We thus provide:

A method of manufacturing optoelectronic components including providing a plurality of optoelectronic semiconductor chips embedded in a carrier layer, wherein a conversion layer is applied to the optoelectronic semiconductor chips and the carrier layer, creating markings in and/or on the conversion layer, and severing the carrier layer to obtain optoelectronic devices, the optoelectronic devices each having at least one of the markings, wherein the at least one marking is at least one recess in the conversion layer.

An optoelectronic device including an optoelectronic semiconductor chip embedded in a carrier layer, a conversion layer deposited on the optoelectronic semiconductor chip and the carrier layer, and at least one marking in and/or on the conversion layer, wherein the at least one marking is at least one recess in the conversion layer, and the at least one marker extends at least partially along a side edge of the optoelectronic device.

A flashing light including at least one optoelectronic device including an optoelectronic semiconductor chip embedded in a carrier layer, a conversion layer deposited on the optoelectronic semiconductor chip and the carrier layer, and at least one marking in and/or on the conversion layer, wherein the at least one marking is at least one recess in the conversion layer, and the at least one marker extends at least partially along a side edge of the optoelectronic device.

### BRIEF DESCRIPTION OF THE DRAWINGS

FIGS. 1A to 1E schematically show illustrations of an example of a process for manufacturing optoelectronic components with markings in the form of sawn recesses in the conversion layer.

FIGS. 2A to 2E schematically show displays of an example of a method of manufacturing optoelectronic devices with markings printed on the conversion layer.

FIGS. 3A to 3E schematically show representations of an example of a method of manufacturing optoelectronic devices having markings in the conversion layer produced by masked UV exposure.

FIGS. 4A to 4F schematically show representations of an example of a process for manufacturing optoelectronic devices with catalyst-generated markings in the conversion layer.

### LIST OF REFERENCE SIGNS

10 Panel
11 Saw film
12 LED semiconductor chip
13 first main surface
14 second main surface
15 Side face
16 Contact surface
20 Carrier layer
21 Conversion layer
22 Recess
25 Marking
30 Mask
31 UV light
40 Catalyst material
100 optoelectronic device
200 optoelectronic device
300 optoelectronic device
400 optoelectronic device

### DETAILED DESCRIPTION

Our method of manufacturing optoelectronic devices comprises providing a plurality of optoelectronic semiconductor chips embedded in a carrier layer. Furthermore, a conversion layer is provided on the optoelectronic semiconductor chips and the carrier layer. Markings are then generated in and/or on the conversion layer. After the markings have been generated, the carrier layer and, if necessary, further layers such as the conversion layer, are cut through to obtain individual optoelectronic components. The optoelectronic components each have at least one of the markings.

The body or module containing the optoelectronic semiconductor chips embedded in the carrier layer and the conversion layer applied to it can also be referred to as a panel. The term “panel” is an English term that can be translated literally as “plate” and is a technical term commonly used in German by those skilled in the art to describe an intermediate product in the manufacture of components having a plurality of semiconductor chips embedded in a carrier material.

In the panel, the optoelectronic semiconductor chips are no longer in a semiconductor wafer compound, but have already been separated, for example, by sawing. The optoelectronic semiconductor chips can each have a first main surface, a second main surface opposite the first main surface, and a plurality of side surfaces, in particular four side surfaces, by which the first and second main surfaces are connected to one another. The optoelectronic semiconductor chips may be arranged with a predetermined spacing in the panel and embedded in the carrier layer such that the side surfaces of the optoelectronic semiconductor chips are covered by the material of the carrier layer. In particular, the first main surface and/or the second main surface of the optoelectronic semiconductor chips may not be covered by the carrier layer.

The conversion layer can be continuous and extend over the optoelectronic semiconductor chips and the carrier layer. The main surfaces of the optoelectronic semiconductor chips and the surface of the carrier layer, on which the conversion layer is jointly deposited, can be flush.

The optoelectronic semiconductor chips can be of the flip-chip type, for example. In a flip-chip type semiconductor chip, all electrical contact areas are located on one side of the semiconductor chip. The flip-chip type optoelectronic semiconductor chips may be arranged in the panel such that those major surfaces of the optoelectronic semiconductor chips on which the electrical contact pads are arranged face away from the conversion layer.

Furthermore, a redistribution layer (RDL) can be arranged on the side of the panel facing away from the conversion layer. The redistribution layer contains conductor tracks that connect electrical contact areas of the optoelectronic semiconductor chips with external contact elements, that are arranged laterally offset from the electrical contact areas of the optoelectronic semiconductor chips and can also be located in the area of the carrier layer, for example.

The optoelectronic semiconductor chips can emit light in the visible range such as blue or green light, ultraviolet (UV) light, and/or infrared (IR) light.

For example, the optoelectronic semiconductor chips can be light-emitting diodes (LEDs), organic light-emitting diodes (OLEDs), light-emitting transistors or organic light-emitting transistors. Furthermore, the optoelectronic semiconductor chips can be lasers. They can also be components of integrated circuits.

The optoelectronic semiconductor chips can be surface emitters, where the light exits only at one main surface, but they can also be volume emitters, where the light exits at one main surface and additionally at adjacent side surfaces.

The conversion layer, also called converter layer or phosphor layer, converts or can convert the light emitted by the optoelectronic semiconductor chips into light with a different wavelength. In other words, the conversion layer is designed to convert a primary radiation generated by the optoelectronic semiconductor chips. Primary radiation entering the respective conversion layer is at least partially converted into secondary radiation in the conversion layer. In this example, the secondary radiation comprises wavelengths that differ from the wavelengths of the primary radiation, i.e., are longer or shorter than the wavelengths of the primary radiation.

The conversion layer may contain conversion particles that cause conversion of the light emitted from the optoelectronic semiconductor chips. For example, phosphor particles may be included as conversion particles in the conversion layer. Phosphor can be used as a blue light converter to generate white light from the blue light.

Furthermore, the conversion layer can contain quantum dots (QD) for conversion of the light emitted by the optoelectronic semiconductor chips. Quantum dots are nanoscopic material structures, usually made of a semiconductor material, for example, InGaAs, CdSe or GaInP/InP. Charge carriers in a quantum dot are restricted in their mobility in all spatial directions to such an extent that their energy can no longer assume continuous but only discrete values. Quantum dots thus behave similarly to atoms, but their shape, size or the number of electrons in them can be influenced. This allows electronic and optical properties of quantum dots to be tailored.

Within the conversion layer, the conversion particles or quantum dots may be embedded in a material or matrix, for example, of a polymer such as epoxy, silicone or polysiloxane, or a ceramic or glass.

The carrier layer in which the optoelectronic semiconductor chips are embedded can be light-reflecting and, in particular, appear white to an observer. The light reflection can be caused by reflective particles contained in the carrier layer. For example, the reflective particles may consist of titanium dioxide (TiO2).

Reflective in this context means that the reflective particles are substantially reflective for at least part of the light emitted by the optoelectronic semiconductor chips or at least for light in a certain wavelength range.

The reflective particles can be embedded in a material or matrix, for example, made of a plastic, an epoxy resin or a silicone. The carrier layer can be applied to the individual optoelectronic semiconductor chips by a molding or dispensing process, for example.

The conversion layer can be applied to the carrier layer as well as the optoelectronic semiconductor chips after embedding the optoelectronic semiconductor chips into the carrier layer.

The panel with the optoelectronic semiconductor chips embedded in the carrier layer and the conversion layer can be cut through by sawing to obtain the individual optoelectronic components.

Each optoelectronic component may, for example, contain exactly one optoelectronic semiconductor chip embedded in the material of the carrier layer. However, an optoelectronic device may also include other semiconductor chips and/or other components. The carrier material may form a package or housing for the optoelectronic semiconductor chip.

The optoelectronic devices can be chip-scale packages (CSP), also called chip-scaled packages. The term “chip-scale package” is a technical term commonly used by those skilled in the art and refers to a package for a semiconductor chip of the size of the semiconductor chip. For example, a chip-scale package may be defined such that a major surface area of the chip-scale package is at most 20% larger than a major surface area of the semiconductor chip contained in the chip-scale package.

The markings in and/or on the conversion layer can have any suitable shape. For example, the markings can be elongated or dot-shaped, consist of one or more strips, or be arranged in a corner or on a side edge of the optoelectronic component.

For example, the markings may each indicate a predetermined major surface and/or a predetermined polarity and/or a predetermined orientation of the optoelectronic semiconductor chip.

By applying the markings to the conversion layer, an additional frame carrying the markings can be dispensed with. As a result, the optoelectronic components can be manufactured more cost-effectively and compactly. Furthermore, the markings do not reduce the service life and reliability of the optoelectronic components.

Furthermore, the markings can be generated laterally offset from light-emitting areas of the optoelectronic semiconductor chips. In particular, the markings can be generated not directly above the light-emitting areas of the optoelectronic semiconductor chips or not directly above the optoelectronic semiconductor chips, but above the carrier layer. This means that there is also no overlap between the markings and the light-emitting regions of the optoelectronic semiconductor chips. In other words, the markings are located completely outside the outlines of the light-emitting regions of the optoelectronic semiconductor chips. This prevents the properties of the conversion layers of the optoelectronic devices from being affected by the markings.

The optoelectronic components can be incorporated in particular in flash lights, i.e., lighting devices for photographs. Due to the compact size of the optoelectronic components, they are particularly suitable for flash lights in mobile devices, in particular mobile telephones or smartphones. Furthermore, it is possible to use the optoelectronic components in other devices as well, for example, in lighting devices. The optoelectronic components can be used, for example, in vehicle exterior lighting such as headlights, but also in vehicle interior lighting, for example, ambient lighting.

The markings may be printed on the conversion layer, for example, using an inkjet printer or ink-jet printer.

Material of the conversion layer may be removed to create the markings. This allows recesses to be created in the conversion layer. These recesses can, for example, extend through the conversion layer to the carrier layer. If the carrier layer has a different color than the conversion layer, the marking will stand out from the conversion layer to an observer or an optical sensor due to a color contrast. However, only enough material can be removed from the conversion layer so that the carrier layer shows through the remaining conversion layer.

Furthermore, it is possible that the two preceding examples are combined, i.e., markings are created by printing and other markings are created by removing conversion material on one and the same panel.

When removing conversion material, the material can be removed mechanically. In particular, the material can be removed by sawing using a saw blade.

It is also possible to create markings in or on the conversion layer by a laser beam. However, the laser beam possibly damages the conversion layer, which may have an impact on reliability, conversion efficiency and the optical properties of the conversion layer, in particular the homogeneity in terms of brightness and color. Compared to the laser beam treatment, the other methods described herein for generating the markings in and/or on the conversion layer do not cause damage to the conversion layer, in particular the phosphor, and also provide higher conversion efficiency.

The conversion layer may have a curable material component, for example, silicone that is not cured or at least not fully cured when the panel is provided. The curable material component is cured except for the areas where the markings are to be created. Subsequently, the uncured material of the conversion layer can be removed to create the markings in the form of recesses in the conversion layer.

If the curable material component is curable by light of a specific wavelength, for example, UV light, the conversion layer can be exposed to light of a suitable wavelength or range of wavelengths, except for the areas where the markings are to be generated. The exposure can be made through a mask. The areas of the conversion layer covered by the mask are not cured. The uncured conversion material can then be removed to create the desired recesses in the conversion layer.

Furthermore, before the conversion layer is applied to the carrier material and the optoelectronic semiconductor chips embedded in the carrier material, a catalyst material may be applied to the carrier layer and/or the optoelectronic semiconductor chips at the locations where the markings are to be generated later. Subsequently, the conversion layer is applied to the carrier layer, the optoelectronic semiconductor chips and the catalyst material and cured. The catalyst material is configured to inhibit curing of the curable material component of the conversion layer. For example, sulfur compounds as catalyst material can inhibit curing of silicone in the conversion layer. Subsequently, the uncured conversion material can be removed.

An optoelectronic device according to one example comprises an optoelectronic semiconductor chip embedded in a carrier layer, a conversion layer disposed on the optoelectronic semiconductor chip and the carrier layer, and at least one marker in and/or on the conversion layer.

The optoelectronic device may have the examples described above in connection with the method of manufacturing optoelectronic devices.

A flash light according to a further example comprises one or more of the optoelectronic components described herein. The flash light can be incorporated in particular in mobile devices, in particular mobile telephones or smartphones.

In the following, reference is made to the accompanying drawings, which form a part of this description and in which specific examples may be practiced are shown for illustrative purposes. Since components of examples may be positioned in a number of different orientations, the directional terminology is for illustrative purposes and is not limiting in any way. Other examples may be used and structural or logical changes may be made without departing from the scope of this disclosure. The features of the various examples described herein may be combined with each other, unless specifically indicated otherwise. Therefore, the following detailed description is not to be construed in a limiting sense. In the figures, identical or similar elements are provided with identical reference signs where appropriate.

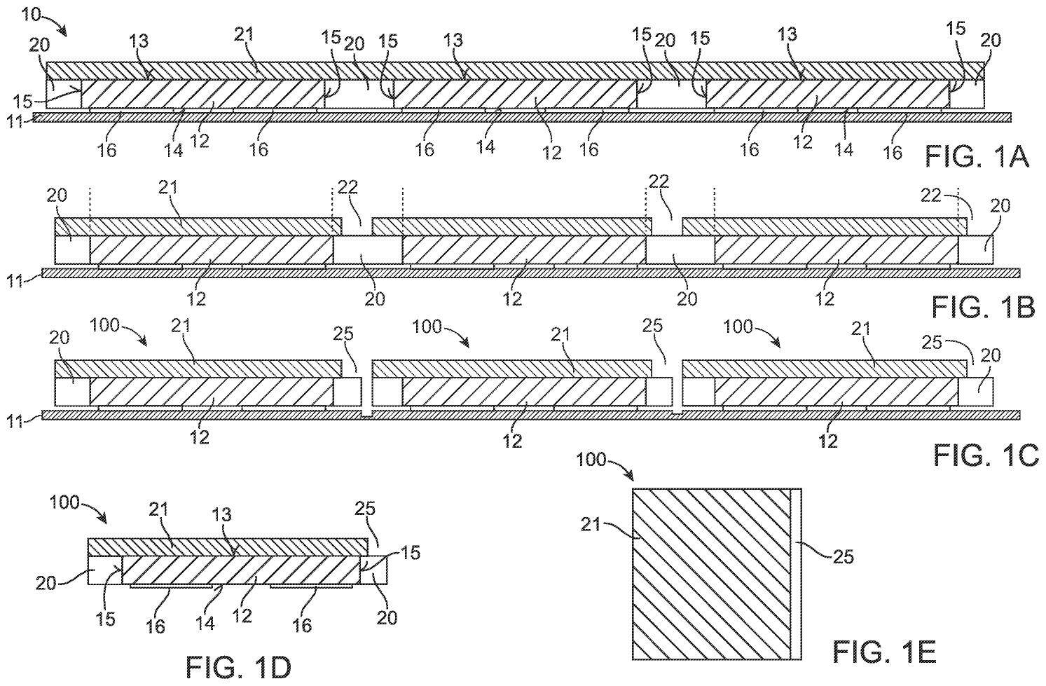

FIGS. 1A to 1E schematically show a method of manufacturing optoelectronic components. An optoelectronic component 100 manufactured by the method is schematically shown in FIGS. 1D and 1E.

In FIG. 1A, a cross-sectional view of a provided panel 10 placed on a saw foil 11 is shown. The panel 10 includes a plurality of optoelectronic semiconductor chips in the form of LED semiconductor chips 12. In FIG. 1A, three LED semiconductor chips 12 are shown as an example, but the panel 10 may include a different number of LED semiconductor chips 12.

The LED semiconductor chips 12 each have a first main surface 13 and a second main surface 14 opposite to the first main surface 13, and a plurality of side surfaces 15 by which the first and second main surfaces 13, 14 are connected to each other. The first major surfaces 14 of the LED semiconductor chips 12 face the saw foil 11.

The LED semiconductor chips 12 are of the flip-chip type. All electrical contact areas 16 of the LED semiconductor chips 12 are located on the first main surface 14.

The LED semiconductor chips 12 are separated from the semiconductor wafer composite and arranged in an array spaced apart from each other.

The LED semiconductor chips 12 are embedded in a carrier layer 20 such that the side surfaces 15 of the LED semiconductor chips 12 are covered by the carrier layer 20, but the first and second main surfaces 13, 14 are not covered by the carrier layer 20. The carrier layer 20 has light-reflecting properties and may have been applied to the LED semiconductor chips 12, for example, by a molding or dispensing process.

The first main surfaces 13 of the LED semiconductor chips 12 are formed flush with the adjacent surface of the carrier layer 20. A conversion layer 21 is deposited on this surface formed by the carrier layer 20 and the first main surfaces 13 of the LED semiconductor chips 12.

In this example, the LED semiconductor chips 12 emit blue light, and the conversion layer 21 contains phosphor particles that convert the light emitted from the LED semiconductor chips 12 into white light. The LED semiconductor chips 12 may be surface emitters that emit light only at the first major surface 13. Alternatively, the LED semiconductor chips 12 may be volume emitters that additionally emit light at the side surfaces 15.

In FIG. 1B, a part of the conversion layer 21 is removed by sawing to form recesses 22 in the conversion layer 21. In this example, the recesses 22 extend completely through the conversion layer 21 in a vertical direction, i.e., in a direction perpendicular to a main surface of the conversion layer 21. Consequently, in the region of the recesses 22, the surface of the support layer 20 is exposed.

The recesses 22 are laterally offset from light emitting regions, i.e., optically active regions, of the LED semiconductor chips 12. Consequently, the recesses 22 are not located above optically active regions and do not overlap such regions. The recesses 22 are located entirely above the carrier layer 20 and are outside the outlines of the optoelectronic semiconductor chips 12 indicated by dashed lines in FIG. 1B.

In FIG. 1C, the optoelectronic components 100 are separated. For this purpose, the carrier layer 20 and the conversion layer 21 are cut through at suitable points by a saw blade. Furthermore, the carrier layer 20 is cut through in the area of the recesses 22. The saw blade used to separate the optoelectronic components 100 is thinner than the saw blade used to create the recesses 22. As a result, each of the optoelectronic components 100 has a marking 25 which has emerged from one of the recesses 22.

After separation, the optoelectronic components 100 are removed from the saw foil 11 and can be incorporated into suitable devices, for example, flash lights. As an example, one of the optoelectronic components 100 is shown in FIG. 1D in cross-section and in FIG. 1E in a top view from above.

The optoelectronic device 100 includes exactly one LED semiconductor chip 12. All or at least two of the side surfaces 15 of the LED semiconductor chip 12 are covered by the substrate layer 20.

Further, the optoelectronic device 100 is a chip-scale package. The two main surfaces of the optoelectronic device 100 each have an area that is at most 20% larger than one of the two main surfaces 13, 14 of the LED semiconductor chip 12.

As can be seen from FIG. 1E, the marking 25 extends along a side edge of the optoelectronic component 100. The white surface of the carrier layer 20 exposed by the marking 25 stands out in color from the yellow conversion layer 21. The marking 25 may identify a polarity or orientation of the LED semiconductor chip 12 included in the optoelectronic device 100. For example, the marking 25 may be arranged on the side of the LED semiconductor chip 12 on which the anode or the cathode of the LED semiconductor chip 12 is located.

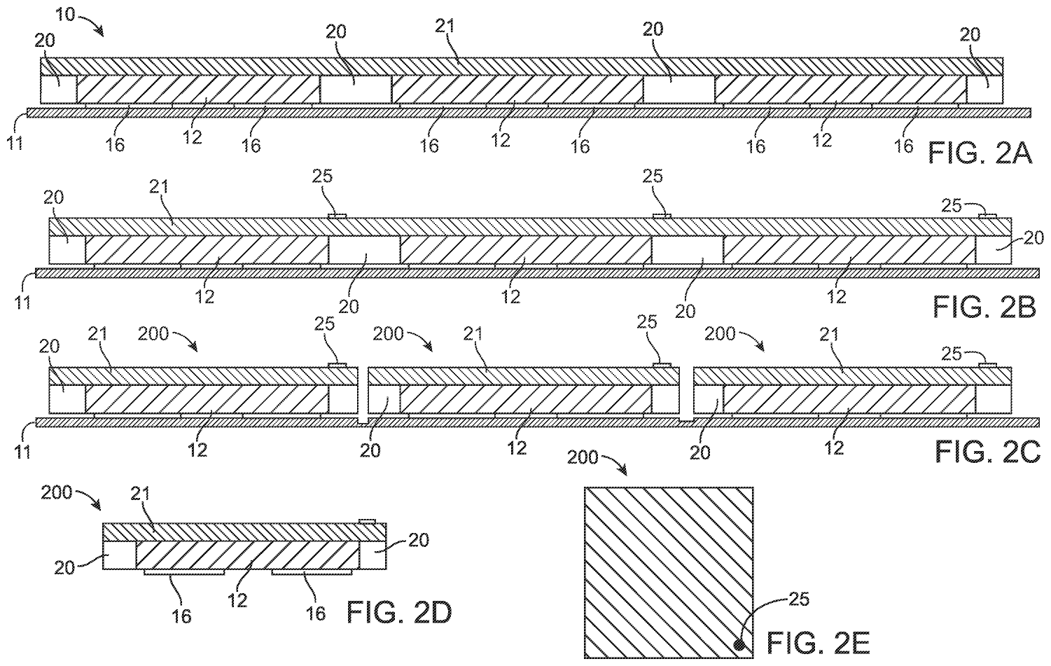

FIGS. 2A to 2E schematically show a further method of manufacturing optoelectronic components. An optoelectronic component 200 manufactured by the method is schematically shown in FIG. 2D in cross-section and in FIG. 2E in a top view from above.

The process illustrated in FIGS. 2A to 2E is similar in many respects to the process illustrated in FIGS. 1A to 1E. Therefore, only the differences between the two processes are described below.

The panel 10 shown in FIG. 2A corresponds to the panel 10 in FIG. 1A. In FIG. 2B, unlike FIG. 1B, material is not removed from the conversion layer 21, but instead markings 25 are printed on the top surface of the conversion layer 20 using a suitable ink and an ink jet printer. The markings 25 can, for example, be elongated or dot-shaped or have another shape.

The markings 25 are printed on the conversion layer 21 laterally offset from light-emitting regions of the optoelectronic semiconductor chips 12, and also do not overlap such regions or are located completely outside the outlines of such regions.

As shown in FIG. 2C, the optoelectronic components 200 are then separated.

The optoelectronic component 200 shown in FIGS. 2D and 2E differs from the component 100 shown in FIGS. 1D and 1E only in the marking 25, in particular its shape and placement. FIG. 2E shows that the marking 25 printed on the conversion layer 21 is dot-shaped and is arranged in a corner of the optoelectronic component 200. Alternatively, the marking 25 may have another suitable shape and be printed at a different location on the optoelectronic device 200. The marking 25 stands out from the yellow conversion layer 21 by its color, for example, black, white or silver.

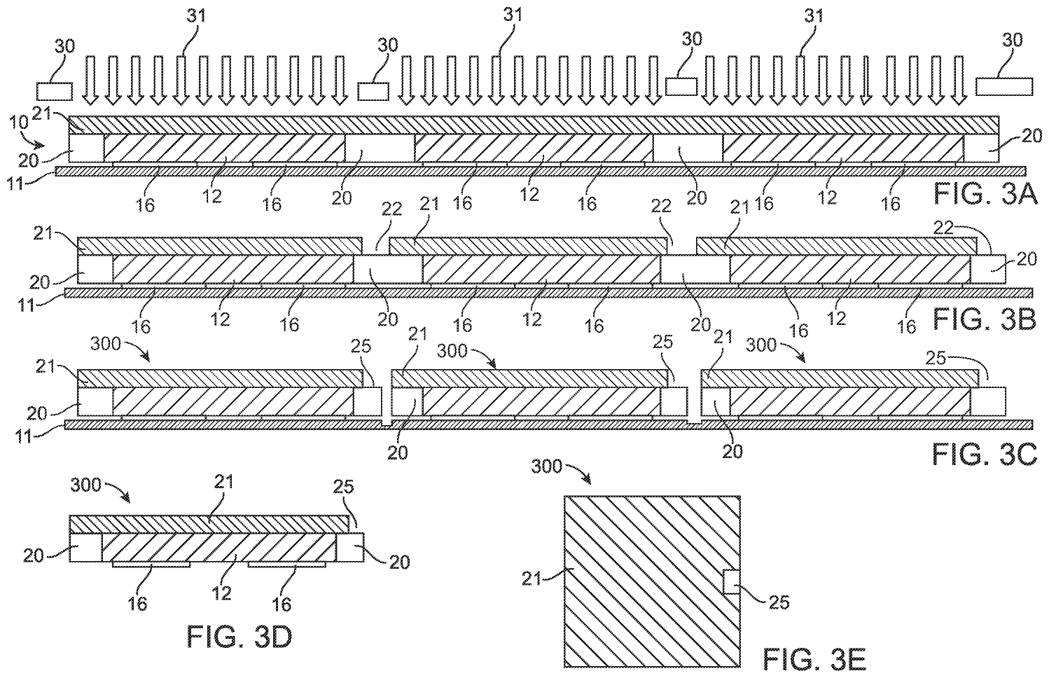

FIGS. 3A to 2E schematically show another method of manufacturing optoelectronic components. An optoelectronic component 300 manufactured by the method is schematically shown in FIG. 3D in cross-section and in FIG. 3E in a top view from above.

The process illustrated in FIGS. 3A to 3E is similar in many respects to the process illustrated in FIGS. 1A to 1E. Therefore, only the differences between the two processes are described below.

The panel 10 shown in FIG. 3A corresponds to the panel 10 in FIG. 1A. However, the conversion layer 21 in FIG. 3A consists of a UV-curable silicone film. For curing, the silicone film is exposed to UV light 31 through a mask 30. The areas of the silicone film that are covered by the mask 30 are not exposed to the UV light 31 so that these areas do not cure and the conversion material can be removed there. This results in recesses 22 in the conversion layer 21 that correspond to the recesses 22 of FIG. 1B and are not located above the LED semiconductor chips 12, but above the carrier layer 20.

In FIG. 3C, the optoelectronic components 300 are separated by sawing analogous to FIG. 1C. FIG. 3E shows that the marking 25 is arranged in the form of a recess on one side of the optoelectronic component 300, but unlike the optoelectronic component 100 shown in FIG. 1E, it does not extend along the entire side. A desired shape and arrangement of the marking 25 can be achieved by a suitably formed mask 30.

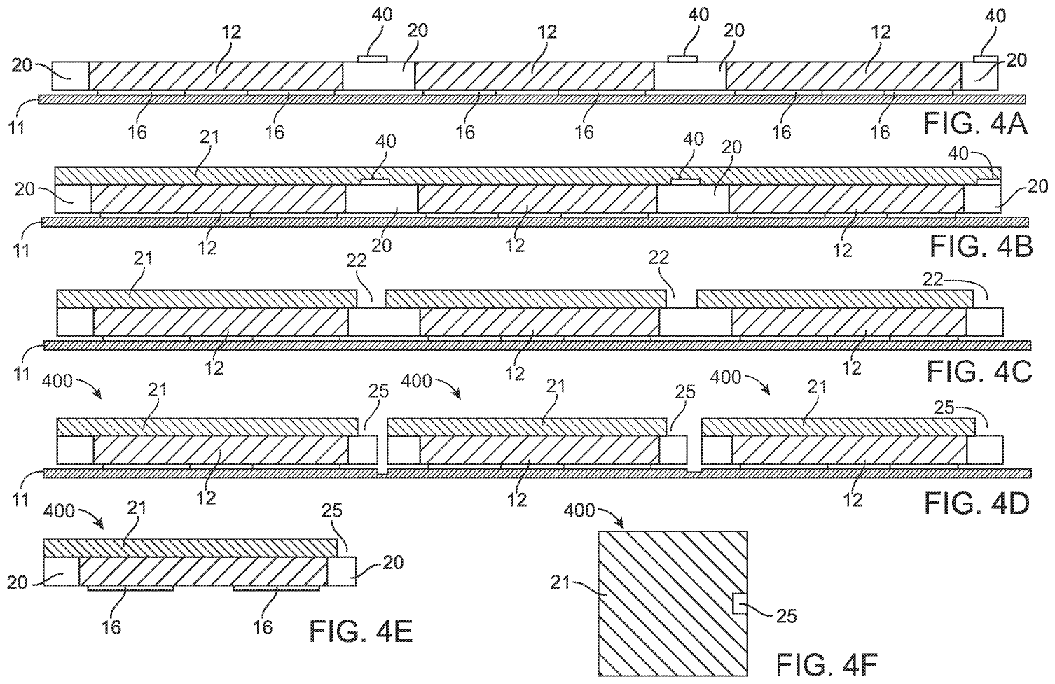

FIGS. 4A to 4F schematically show another method of manufacturing optoelectronic components. An optoelectronic component 400 manufactured by the method is shown schematically in FIG. 4E in cross-section and in FIG. 4F in a top view from above. The basic structure of the optoelectronic device 400 is identical to that of the optoelectronic device 300 shown in FIGS. 3D and 3E. Only the manufacturing processes differ. The differences between the two processes are described below.

In FIG. 4A, the LED semiconductor chips 12 embedded in the carrier layer 20 are provided. At this point, the conversion layer 21 has not yet been applied to the carrier layer 20 and the LED semiconductor chips 12. However, a catalyst material 40 is applied to the substrate layer 20 at the locations where the recesses 22 are to be created later. The catalyst material 40 consists of a suitable sulfur compound.

Then, in FIG. 4B, the conversion layer 21 is applied, which consists of a silicone film. However, the silicone film only cures at the points where it is not in contact with the catalyst material 40 since the catalyst material 40 inhibits the curing of the silicone film. The uncured silicone can be removed, thereby creating the recesses 22 shown in FIG. 4C, which correspond to the recesses 22 shown in FIG. 3B.

The process steps performed in FIGS. 4D and 4E are identical to the process steps shown in FIGS. 3C and 3D.

This disclosure claims priority of DE Application No. 10 2018 125 632.9, filed Oct. 16, 2018. The disclosure of DE Application No. 10 2018 125 632.9 is incorporated herein by reference.

1-14. (canceled)

15. A method of manufacturing optoelectronic components comprising:
providing a plurality of optoelectronic semiconductor chips embedded in a carrier layer, wherein a conversion layer is applied to the optoelectronic semiconductor chips and the carrier layer,
creating markings in and/or on the conversion layer, and
severing the carrier layer to obtain optoelectronic devices, the optoelectronic devices each having at least one of the markings,
wherein the at least one marking is at least one recess in the conversion layer.

16. The method of claim 15, wherein the markings are generated laterally offset from light emitting regions of the optoelectronic semiconductor chips.

17. The method according to claim 15, wherein material of the conversion layer is removed to produce the markings.

18. The method according to claim 17, wherein the material of the conversion layer is removed mechanically.

19. The method of claim 17, wherein the conversion layer comprises a curable material component and the curable material component is cured except for the areas where the markings are created.

20. The method according to claim 19, wherein, to cure the curable material component, the conversion layer is exposed to light except for areas where the markings are generated.

21. The method according to claim 19, wherein a catalyst material is applied to the carrier layer and/or the optoelectronic semiconductor chips prior to application of the conversion layer at the areas where the markings are generated, and subsequently the conversion layer is applied to the optoelectronic semiconductor chips, the carrier layer and the catalyst material, the catalyst material adopted such that it inhibits curing of the curable material component of the conversion layer.

22. The method according to claim 15, wherein the support layer is reflective.

23. The method according to claim 15, wherein the optoelectronic devices are chip-scale packages.

24. An optoelectronic device comprising:
an optoelectronic semiconductor chip embedded in a carrier layer,
a conversion layer deposited on the optoelectronic semiconductor chip and the carrier layer, and
at least one marking in and/or on the conversion layer,
wherein the at least one marking is at least one recess in the conversion layer, and
the at least one marker extends at least partially along a side edge of the optoelectronic device.

25. The optoelectronic device of claim 24, wherein the at least one marker is laterally offset from a light emitting region of the semiconductor optoelectronic chip.

26. The optoelectronic device according to claim 24, wherein the carrier layer is reflective.

27. The optoelectronic device according to claim 24, wherein the optoelectronic device is a chip-scale package.

28. A flashing light comprising at least one optoelectronic device according to claim 24.
